(19) United States
(12) Patent Application Publication
(10) Pub. No.: US 2026/0143805 A1
(43) Pub. Date: May 21, 2026

(54) INTEGRATED CIRCUIT DEVICE AND MANUFACTURING METHOD THEREOF

(71) Applicant: TAIWAN SEMICONDUCTOR MANUFACTURING COMPANY, LTD., Hsinchu (TW)

(72) Inventors: Kuan-Kan HU, Hsinchu (TW); Che Chi SHIH, Taoyuan City (TW); Zhi-Chang LIN, Hsinchu County (TW); Ku-Feng YANG, Hsinchu County (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 18/951,211

(22) Filed: Nov. 18, 2024

(51) Int. Cl. H01L 27/092; H01L 21/8238

(52) U.S. Cl. CPC H10D 84/856; H10D 84/0167; H10D 84/0188; H10D 84/038

(57) ABSTRACT

A method for manufacturing an integrated circuit device is provided. The method includes forming a bottom epitaxial stack over a bottom substrate; forming a top epitaxial stack over the bottom epitaxial stack; patterning the top epitaxial stack and the bottom epitaxial stack into a first fin and a second fin; removing a first portion of the top epitaxial stack from the second fin, wherein a second portion of the top epitaxial stack remains in the first fin; epitaxially growing a first bottom source/drain epitaxial structure and a second bottom source/drain epitaxial structure on a side of the bottom channel layer in the first fin and a side of the bottom channel layer in the second fin, respectively; and epitaxially growing a top source/drain epitaxial structure on a side of the top channel layer in the first fin.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET structure in accordance with some embodiments of the present disclosure.

FIGS. 2-12B illustrate schematic views of intermediate stages in the manufacture of an integrated circuit device in accordance with some embodiments of the present disclosure.

FIG. 13 is a perspective view of an example CFET structure in accordance with some embodiments of the present disclosure.

FIGS. 14-23B illustrate schematic views of intermediate stages in the manufacture of an integrated circuit device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices (e.g., planar transistors) that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a GAA transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents. Stacked transistor structures, such as complementary field effect transistors (CFETs) including vertically stacked p-type FETs and n-type FETs, can provide further reduced footprint and density improvement for advanced IC technology nodes (particularly as IC technology nodes advance to 3 nm (N3) and below).

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

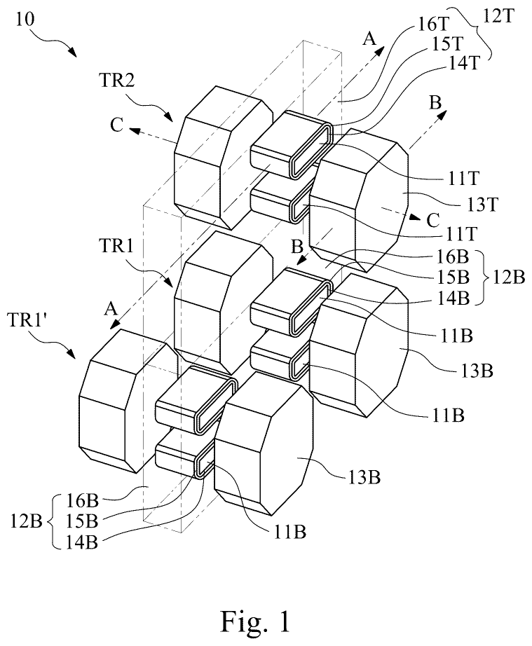

FIG. 1 is a perspective view of an example CFET structure 10 in accordance with some embodiments of the present disclosure. In some embodiments of the present disclosure, a CFET structure 10 includes a bottom transistor TR1 and a top transistor TR2 vertically stacked over the bottom transistor TR1. In some embodiments, the bottom transistor TR1 and the top transistor TR2 are GAA FET transistors. The bottom transistor TR1 includes bottom semiconductor channel layers 11B disposed one above another, a bottom gate structure 12B wrapping around each of the bottom semiconductor channel layers 11B, and bottom source/drain epitaxy structures 13B on opposite sides of each of the bottom semiconductor channel layers 11B. The top transistor TR2 includes top semiconductor channel layers 11T vertically stacked one above another, a top metal gate structure 12T wrapping around each of the top semiconductor channel layers 11T, and top source/drain epitaxy structures 13T on opposite sides of each of the top semiconductor channel layers 11T. The bottom gate structure 12B may include an interfacial layer 14B, a high-k gate dielectric layer 15B around the interfacial layer, and one or more gate metal layers 16B around the high-k gate dielectric layer 15B. The top gate structure 12T may include an interfacial layer 14T, a gate dielectric layer 15T, and a one or more gate metal layers 16T. In some embodiments, the top gate structure 12T can be electrically isolated from bottom gate structure 12B by dielectric bonding materials (not shown), as will be described in greater detail below. In some embodiments, the bottom transistor TR1 has a first conductivity type (e.g., n-type) and the top transistor TR2 has a second conductivity type (e.g., p-type) different from the first conductivity type.

In some embodiments of the present disclosure, a cut nanosheet process is performed to remove a top transistor from a CFET structure 10, and leave a bottom transistor. As shown in FIG. 1, a bottom transistor TR1′ is next to the bottom transistor TR1, in which the bottom transistor TR1′ has a same configuration as that of the bottom transistor TR1, and the CFET structure 10 has no top transistor over the bottom transistor TR1′. For example, there are no top semiconductor channel layers 11T and top source/drain epitaxy structures 13T above the bottom transistor TR1′. With the configuration, effective capacitance is reduced, thereby optimizing circuit performance (e.g., static random-access memory (SRAM) performance).

FIG. 1 further illustrates reference cross-sections that are used in later figures. Cross-section A-A is along a longitudinal axis of gate structures 12B, 12T and in a direction, for example, perpendicular to the direction of current flow between the epitaxial source/drain structures 13B of the bottom transistor TR1 and the direction of current flow between the epitaxial source/drain structures 13T of the top transistor TR2. Cross-section B-B is parallel to cross-section A-A and extends through epitaxial source/drain structures 13B of the bottom transistor TR1 and epitaxial source/drain structures 13T of the top transistor TR2. Cross-section C-C is perpendicular to cross-sections A-A and B-B and is parallel to the direction of current flow between the epitaxial source/drain structures 13B of the bottom transistor TR1 and the direction of current flow between the epitaxial source/drain structures 13T of the top transistor TR2. Subsequent figures refer to these reference cross-sections for clarity.

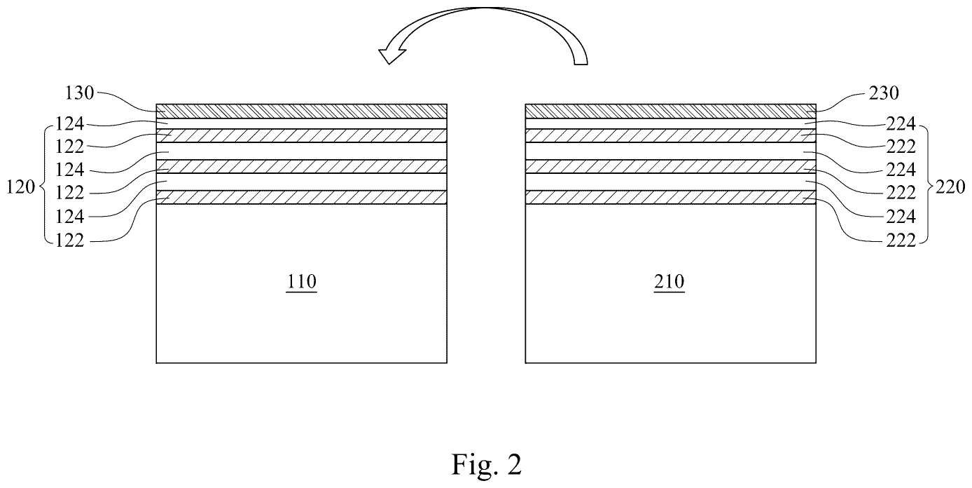

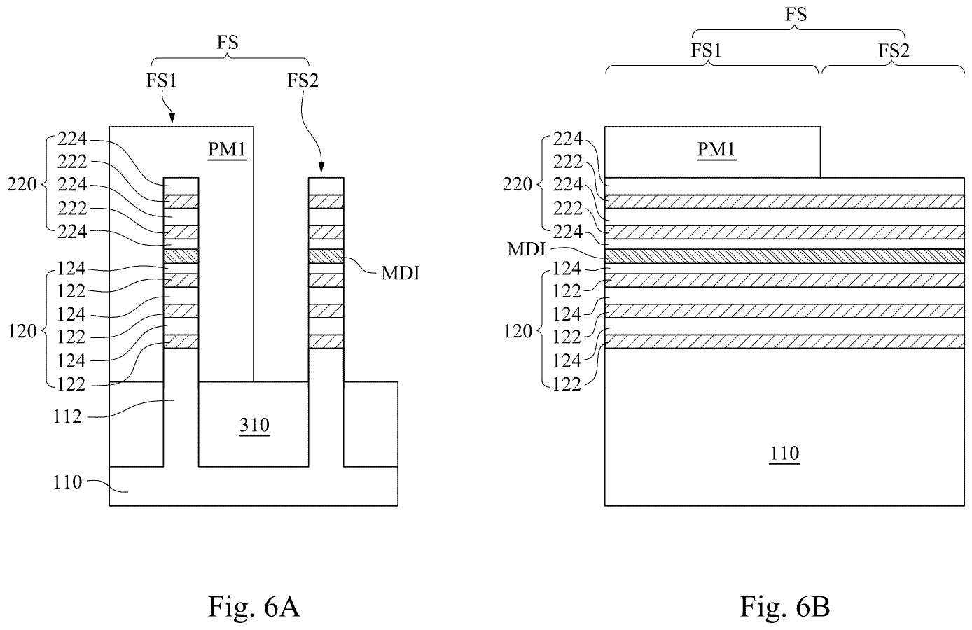

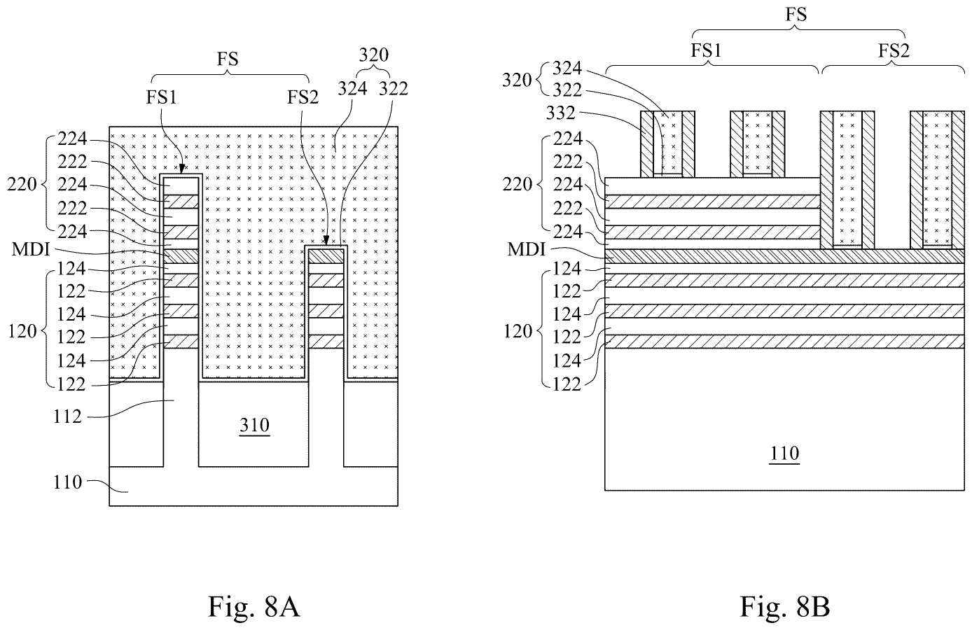

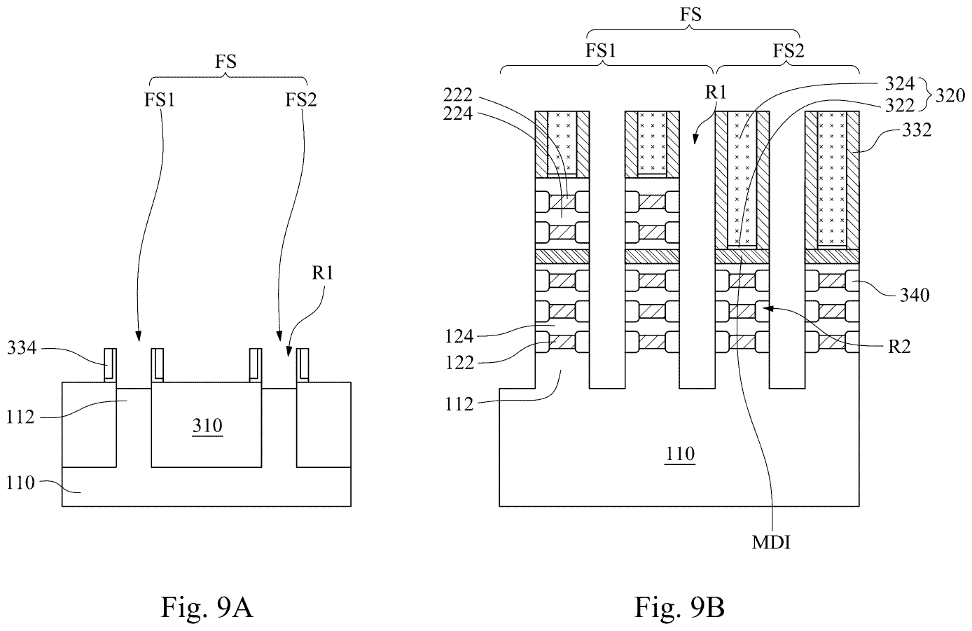

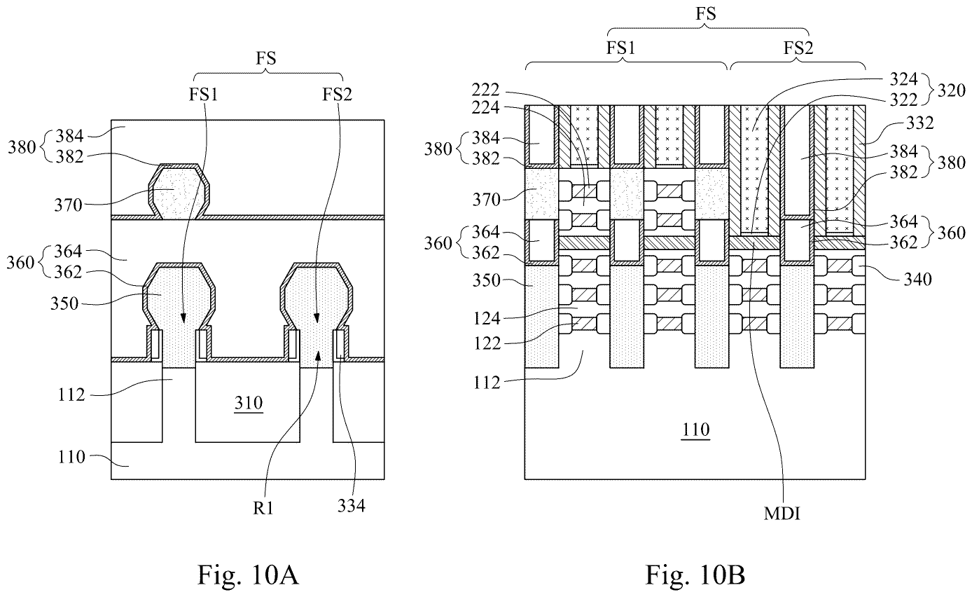

FIGS. 2-12B illustrate schematic views of intermediate stages in the manufacture of an integrated circuit device in accordance with some embodiments of the present disclosure. FIGS. 2-5, 6A, and 7A are cross-sectional views of the integrated circuit device (e.g., taken along line A-A or B-B in FIG. 1) at various manufacturing stages in accordance with some embodiments. FIGS. 8A, 11A, and 12A are cross-sectional views of the integrated circuit device (e.g., taken along line A-A in FIG. 1) at various manufacturing stages in accordance with some embodiments. FIGS. 9A and 10A are cross-sectional views of the integrated circuit device (e.g., taken along line B-B in FIG. 1) at various manufacturing stages in accordance with some embodiments. FIGS. 6B, 7B, 8B, 9B, 10B, 11B, and 12B are cross-sectional views of the integrated circuit device (e.g., taken along line C-C in FIG. 1) at various manufacturing stages in accordance with some embodiments. It is understood that additional steps may be provided before, during, and after the steps shown in FIGS. 2-12B, and some of the steps described below can be replaced or eliminated for additional embodiments of the method. The order of the operations/processes may be interchangeable.

Reference is made to FIG. 2. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes sacrificial layers 122 and channel layers 124 stacked in a sequence over the substrate 110. In some embodiments, the layers 122 and 124 may include SiGe with various semiconductor compositions. For example, a Si concentration in the sacrificial layers 122 is less than a Si concentration in the channel layers 124. Stated differently, in some embodiments, a Ge concentration in the sacrificial layers 122 is greater than a Ge concentration in the channel layers 124. For example, the channel layers 124 are SiₓGe₁₋ₓ, the sacrificial layers 122 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 122 include SiGe and the channel layers 124 include Si, the Si oxidation rate of the channel layers 124 is less than the SiGe oxidation rate of the sacrificial layers 122.

The channel layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 124 may be referred to as semiconductor channels in the context.

By way of example, epitaxial growth of the sacrificial layers 122 and the channel layers 124 of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the sacrificial layers 122 and the channel layers 124, include suitable semiconductor material, such as like Si, Ge, Sn, SiGe, GeSn, III-V semiconductor, the like, or the combination thereof. In some embodiments, the channel layers 124 may include a same semiconductor material as that substrate 110. In some embodiments, the epitaxially grown sacrificial layers 122 include a different material than the substrate 110. In some other embodiments, at least one of the sacrificial layers 122 and the channel layers 124 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the sacrificial layers 122 and the channel layers 124 may be chosen based on providing differing oxidation and/or etching selectivity properties.

In some embodiments, the sacrificial layers 122 and the channel layers 124 are intrinsic semiconductor layers, which are not intentionally doped, for example, not having intentionally placed dopants, but rather having a doping resulting from process contaminants. In some embodiments, the sacrificial layers 122 and the channel layers 124 are substantially dopant-free (i.e., having an extrinsic dopant concentration from about 0 cm⁻³ to about 1×10¹⁸ cm⁻³), where for example, no intentional doping is performed during the epitaxial growth process. In some alternative embodiments, the sacrificial layers 122 and the channel layers 124 may be lightly doped for forming a device of a certain conductivity type. For example, for forming an n-type devices, the sacrificial layers 122 and the channel layers 124 may be lightly doped with p-type dopants with dopant concentration from about 0 cm⁻³ to about 1×10¹⁸ cm⁻³. For example, for forming a p-type device, the sacrificial layers 122 and the channel layers 124 may be lightly doped with n-type dopants with dopant concentration from about 0 cm⁻³ to about 1×10¹⁸ cm⁻³.

A bonding layer 130 is formed over the epitaxial stack 120. In some embodiments, the bonding layer 130 is a bonding dielectric layer, including SiO, SiOC, SiOCN, SiN, SION, the like, or the combination thereof. In some embodiments, the bonding layer 130 is formed of a high thermal conductive material such as AN, BN, SiC, diamond, BeO, the like, or the combination thereof. In some embodiments, the bonding layer 130 may include a multi-layer structure for different process requirements, for example bonding purpose, thermal conductivity or etch stop layer (e.g., dielectric or metal oxide, or the like), etc. The bonding layer 130 may be deposited by any suitable technique, including CVD, atomic layer deposition (ALD), or by other suitable deposition processes.

An epitaxial stack 220 is formed over a substrate 210. The epitaxial stack 220 includes sacrificial layers 222 and channel layers 224 stacked in a sequence over the substrate 210. In some embodiments, the channel layers 124 and 224 are for devices of different conductivity types. In some example, the channel layers 124 are for p-type transistors, and the channel layers 224 are for n-type transistors. In some example, the channel layers 124 are for n-type transistors, and the channel layers 224 are for p-type transistors.

A bonding layer 230 is formed over the epitaxial stack 220. In some embodiments, the bonding layer 230 may be formed by one or more different processes, may be formed of a different material, and may have a different thickness than the bonding layer 130. The configuration of the substrate 210, the epitaxial stack 220, and the bonding layer 230 are similar to those of the substrate 110, the epitaxial stack 120, and the bonding layer 130, and thereto not repeated herein.

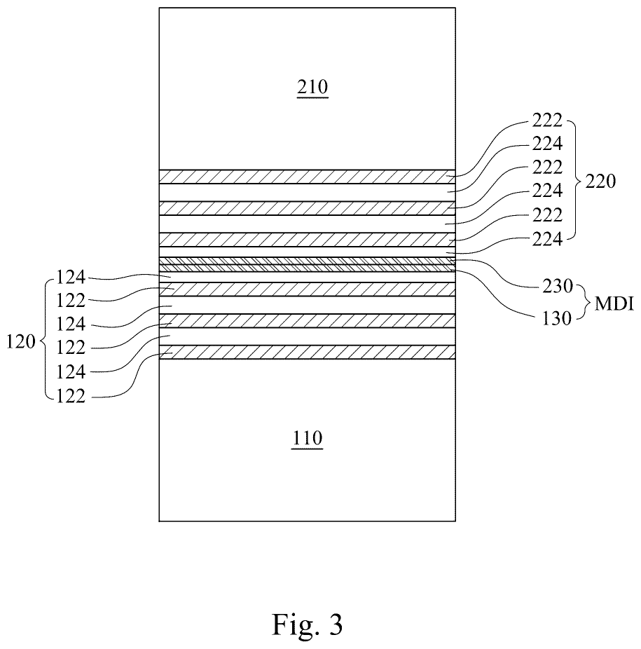

Reference is made to FIG. 3. The substrates 110 and 210 are bonded to one another. For example, the substrate 210 is flipped upside down (e.g., rotated in the direction of the arrow shown in FIG. 2), and the bonding layers 130 and 230 are brought into contact with one another and bonded together by adhesive bonding, thermal bonding, thermocompression bonding, or any suitable bonding technique. The bonding layers 130 and 230 in combination may be referred to as a middle dielectric layer MDI in the context.

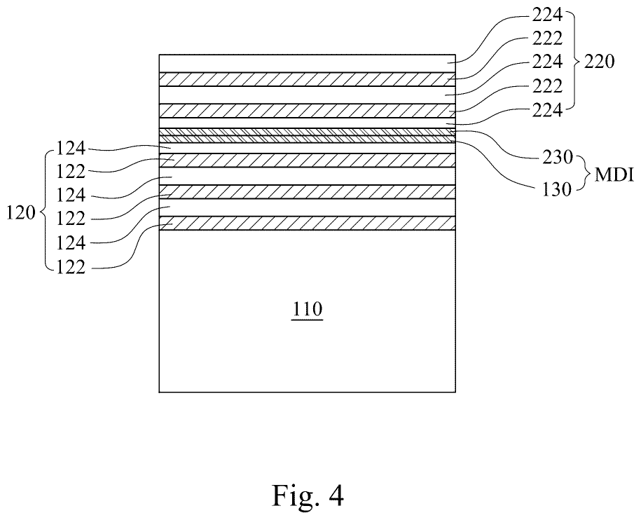

Reference is made to FIG. 4. A wafer thinning down process is performed to a portion of the substrate 210 (referring to FIG. 3), and leaving a remaining portion 210′ on the epitaxial stack 220. The wafer thinning down process may include a polish process (e.g., chemical mechanical polish (CMP) process), an etch process, or the combination thereof. After the wafer thinning down process, the remaining portion of the substrate 210 (referring to FIG. 3) may be referred to as a channel layer 210′. The channel layer 210′ and the channel layers 224 in combination may serve as channels for top transistors.

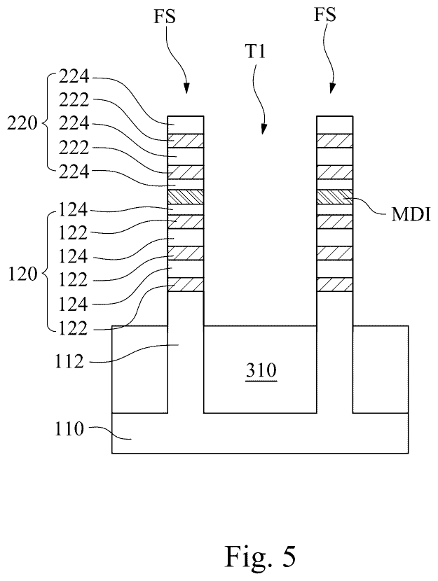

Reference is made to FIG. 5. A plurality of semiconductor fins FS extending from the substrate 210 are formed. In various embodiments, each of the fins FS includes a substrate portion 112 formed from the substrate 110, portions of each of the epitaxial layers of the epitaxial stack 120 including epitaxial layers 122 and 124, a portion of the middle dielectric layer MDI, portions of each of the epitaxial layers of the epitaxial stack 220 including epitaxial layers 222 and 224, and a portion of the channel layer 210′. The fins FS may be fabricated using suitable processes including photolithography and etch processes. The photolithography process may include forming a photoresist layer (not shown) over a hard mask layer over the stack 220, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions through the hard mask layer, through the epitaxial stack 140, the middle dielectric layer MDI, the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stacks 140 and 120. The etching process can include dry etching, wet etching, reactive ion etching (RIE), and/or other suitable processes.

Isolation structures 310 are formed in the trench T1 between the fins FS. The isolation structure 310 may be a single-layer or a multi-layer structure. In some embodiments, the isolation structure 310 includes low-k dielectric materials, SiN, SiCN, SiOC, SiOCN or the like. Formation of the isolation structure 310 may include depositing a dielectric material over the fins FS, followed by an etching back process. Through the etching back process, a top surface of the isolation structure 310 is lowered to a position lower than a bottommost surface of the epitaxial stack 120, such that the sacrificial layers 122, the channel layers 124, sacrificial layers 222, the channel layers 224, and the channel layer 210′ are exposed.

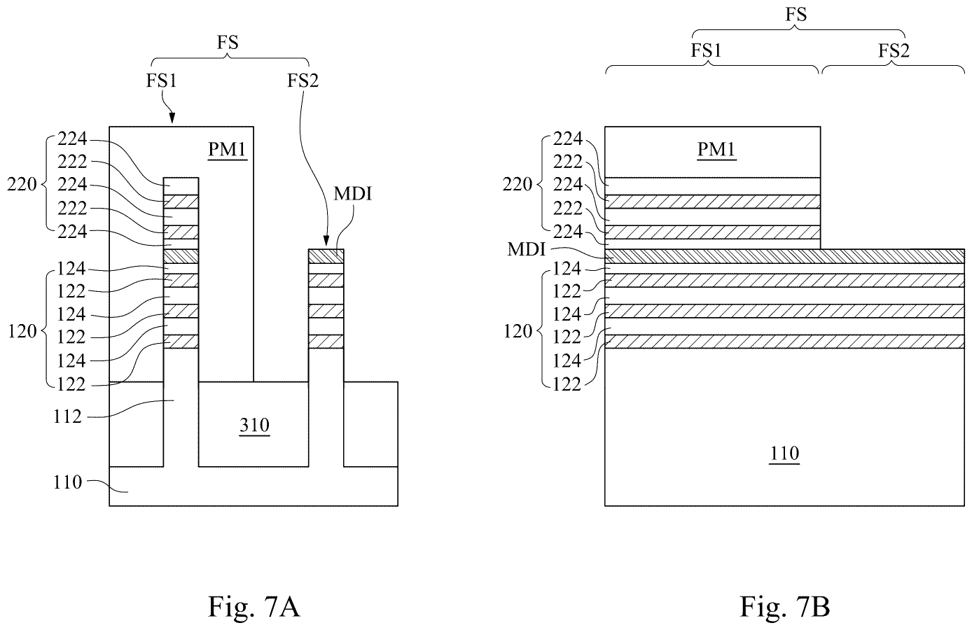

FIGS. 6A-7B illustrate a cut nanosheet process performed to remove the channel layer 210′ and the epitaxial stack 220 in a portion of the fins FS. The cut nanosheet process may include photolithography and etch processes.

In FIGS. 6A and 6B, a patterned mask PM1 is formed to cover a first portion FS1 of the fin FS and expose a second portion FS2 of the fin FS, for example, by a photolithography process. The photolithography process may include forming a photoresist layer (not shown) over a hard mask layer over the stack 220, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process.

Reference is made to FIGS. 7A and 7B. With the patterned mask PM1 in place, an etch process is performed to remove the channel layer 210′ and the epitaxial stack 220 (referring to FIGS. 6A and 6B) from the second portion FS2 of the fin FS. The etch process may include a dry etch, a wet etch, or the combination thereof. The patterned mask PM1 may serve as an etch mask during the etch process, thereby protecting the first portion FS1 of the fin FS from being etched. In some embodiments, the etch process has a first etch rate to the channel layer 210′ and the epitaxial stack 220 (referring to FIGS. 6A and 6B) and a second etch rate to the middle dielectric layer MDI, in which the first etch rate is much greater than the second etch rate. Thus, the middle dielectric layer MDI may serve as an etch stop layer during the etch process, thereby protecting the epitaxial stack 120 in the second portion FS2 of the fin FS from being etched. In some embodiments, the etch process has a first etch rate to the channel layer 210′ and the epitaxial stack 220 (referring to FIGS. 6A and 6B) and a second etch rate to the isolation structure 310, in which the first etch rate is much greater than the second etch rate. Thus, the isolation structure 310 may also serve as an etch stop layer during the etch process. After the etch process, a suitable stripping process is performed to remove the patterned mask PM1 from the substrate 110.

Reference is made to FIGS. 8A and 8B. One or more dummy gate structures 320 are formed on the fins FS. The dummy gate structure 320 may include a gate dielectric 322 and a gate electrode 324. The gate dielectric 322 may include one or more layers of dielectric material, such as silicon oxide, silicon nitride, a high-k dielectric material, and/or other suitable dielectric material. In some embodiments, the gate electrode 324 includes a material different than that of the gate dielectric 322. In some embodiments, the gate dielectric 322 may be deposited by a CVD process, a sub-atmospheric CVD (SACVD) process, a FCVD process, an ALD process, a PVD process, or other suitable process. The gate electrode 324 may include polycrystalline silicon (polysilicon). In some embodiments, the materials of the dummy gate structure 320 are formed by various processes such as layer deposition, for example, CVD, PVD, ALD, thermal oxidation, or other suitable deposition techniques, or combinations thereof.

The dummy gate structures 320 may be formed by first depositing a blanket gate dielectric layer, a gate electrode layer, and a mask layer, followed by a patterning process. For example, the patterning process includes a lithography process (e.g., photolithography or e-beam lithography) and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 320.

Gate spacers 332 are formed on opposite sidewalls of the dummy gate structures 320. The spacers 332 may be made of a dielectric material such as silicon oxide, silicon nitride, silicon carbide, silicon oxynitride, SiCN, silicon oxycarbide, SiOCN, and/or combinations thereof. In some embodiments, each of the spacers 332 includes a single layer or multiple layers. In some embodiments, fin sidewall spacers 334 (referring to FIG. 9A later) are formed on opposite sides of the fins FS. The fin sidewall spacers 334 may be made of a dielectric material such as silicon oxide, silicon nitride, silicon carbide, silicon oxynitride, SiCN, silicon oxycarbide, SiOCN, and/or combinations thereof. The gate spacers 332 or/and the fin sidewall spacers 334 may be formed by first depositing one or more conformal spacer material layers and subsequently etching back the one or more spacer material layers to form the gate spacers 332 or/and the fin sidewall spacers 334. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 332 or/and the fin sidewall spacers 334 on the vertical surfaces, such as the sidewalls of the dummy gate structures 320 and sidewalls of the fins FS.

Reference is made to FIGS. 9A and 9B. After formation of the dummy gate structures 320 and the gate spacers 332, exposed portions of the semiconductor fins FS that extend laterally beyond the gate spacers 332 (e.g., in source/drain regions of the fins FS) are etched by using, for example, an anisotropic etching process that uses the dummy gate structures 320 and the gate spacers 332 as an etch mask, resulting in recesses R1 into the semiconductor fins FS and between corresponding dummy gate structures 320. After the anisotropic etching, end surfaces of the sacrificial layers 122 and the channel layers 124 are exposed by the recesses R1 and aligned with respective outermost sidewalls of the gate spacers 332, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. Through the etching process(es), top ends of the fin sidewall spacers 334 may be lowered to a position below tops of the fins FS. In some alternatively embodiments, the fin sidewall spacers 334 are entirely removed by etching the recesses R1.

The sacrificial layers 122 are laterally or horizontally recessed by using suitable selective etching process, resulting in lateral/sidewall recesses R2 vertically between corresponding channel layers 124, and vertically between the channel layer 124 and the substrate portion 112. The sacrificial layers 222 are laterally or horizontally recessed by using suitable selective etching process, resulting in lateral/sidewall recesses R2 vertically between corresponding channel layers 224, and vertically between the channel layer 224 and 210′. For example, end surfaces of the sacrificial layers 122 and 222 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The substrate portion 112 and the channel layers 124, 224, and 210′ may have a higher etch resistance to the selective etching process than that of the sacrificial layers 122 and 222. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 124, 224, and 210′ and the substrate portion 112 may not be not significantly etched by the process of laterally recessing the sacrificial layers 122 and 222. As a result, the channel layers 124, 224, and 210′ and the substrate portion 112 laterally extend past opposite end surfaces of the sacrificial layers 122 and 222.

Inner spacers 340 are formed in the recesses R2. Stated differently, the inner spacers 340 may be formed on opposite end surfaces of the laterally recessed sacrificial layers 122 and 222. The inner spacers 340 may include a low-k dielectric material, such as SiOₓ, SiON, SiOC, SiN, SiCN, or SiOCN. Formation of the inner spacers 340 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 340 may include a single layer or multiple layers. The inner spacers 340 may serve to isolate metal gates from source/drain regions formed in subsequent processing. In the example of FIG. 9B, sidewalls of the inner spacers 340 are aligned with sidewalls of the channel layers 124.

Reference is made to FIGS. 10A and 10B. Source/drain epitaxial structures 350 are formed in the recess R1, and in contact with opposite sides of the channel layers 124. In some embodiments, the source/drain epitaxial structures 350 may include Ge, Si, GaAs, AlGaAs, SiGe, GaAsP, SiP, or other suitable material. The source/drain epitaxial structures 350 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 350 are not in-situ doped, an implantation process (i.e., a junction implant process) is performed to dope the source/drain epitaxial structures 350. The source/drain epitaxial structures 350 may be formed by performing an epitaxial growth process that provides an epitaxial material on the exposed surfaces of the channel layers 124 and the substrate 110. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 124 and the substrate 110.

After the formation of the source/drain epitaxial structures 350, dielectric structures 360 are formed in the recess R1 and on the source/drain epitaxial structures 350. Each of the dielectric structure 360 may include an etch stop layer (ESL) 362 and an interlayer dielectric (ILD) layer 364 over the ESL 362. In some examples, the ESL layer 362 includes a silicon nitride layer, silicon oxide layer, a silicon oxynitride layer, and/or other suitable materials. The ESL layer 362 may be formed by plasma-enhanced chemical vapor deposition (PECVD) process and/or other suitable deposition or oxidation processes. In some embodiments, the ILD layer 364 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 362. The ILD layer 364 may be deposited by a CVD process or other suitable deposition technique.

In some embodiments of the present disclosure, the topmost channel layer 124 and the bottommost channel layer 222 respectively adjoins a bottom surface and a top surface of the middle dielectric layer MDI. Prior to the formation of the dielectric structures 360, a clean/etch process is performed to lower top surfaces of the source/drain epitaxial structures 350, such that opposite sides of the topmost channel layer 124 adjoining the middle dielectric layer MDI is exposed. The formed dielectric structures 360 is in contact with the opposite sides of the topmost channel layer 124, thereby avoiding a current leakage resulted from the topmost channel layer 124. In some embodiments, after depositing materials of the ESL 382 and the ILD layer 384, an etch process is performed to remove top portions of the ESL 382 and the ILD layer 384 to expose opposite sides of the channel layers 224 and 210′. The etch process may be controlled such that opposite sides of the bottommost channel layer 222 is not exposed by the ESL 382 and the ILD layer 384. Thus, the formed dielectric structures 360 is in contact with the opposite sides of the bottommost channel layer 222, thereby avoiding a current leakage resulted from the bottommost channel layer 222. The topmost channel layer 124 and the bottommost channel layer 222 adjoining the bottom surface and the top surface of the middle dielectric layer MDI may be referred to as dummy channel layers in the context.

In some other embodiments of the present disclosure, the dummy channel layers (e.g., topmost channel layer 124 and the bottommost channel layer 222) may be omitted. Stated differently, the sacrificial layer 122 of the stack 120 and the sacrificial layer 222 of the stack 220 respectively adjoin a bottom surface and a top surface of the middle dielectric layer MDI. In such embodiments, the dielectric structures 360 may be spaced apart from the channel layers 124 and 224.

Source/drain epitaxial structures 370 are formed in the recess R1 on the dielectric structures 360. The source/drain epitaxial structures 370 in contact with opposite sides of the channel layers 224 and 210′. In some embodiments, the source/drain epitaxial structures 370 may include Ge, Si, GaAs, AlGaAs, SiGe, GaAsP, SiP, or other suitable material. The source/drain epitaxial structures 370 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 370 are not in-situ doped, an implantation process (i.e., a junction implant process) is performed to dope the source/drain epitaxial structures 370. The source/drain epitaxial structures 370 may be formed by performing an epitaxial growth process that provides an epitaxial material on the exposed surfaces of the channel layers 224 and 210′. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 224 and 210′.

In some embodiments of the present disclosure, the source/drain epitaxial structures 370 has a conductive type opposite to that of the source/drain epitaxial structures 350. For example, the source/drain epitaxial structures 370 is a n-type source/drain epitaxial structure for an n-type device, and the source/drain epitaxial structures 350 is a p-type source/drain epitaxial structure for a p-type device. And, the source/drain epitaxial structures 350 is a p-type source/drain epitaxial structure for an p-type device, and the source/drain epitaxial structures 370 is a n-type source/drain epitaxial structure for a n-type device.

After the formation of the source/drain epitaxial structures 370, dielectric structures 380 are formed in the recess R1 and on the source/drain epitaxial structures 370. Each of the dielectric structure 380 may include an ESL 382 and an ILD layer 384 over the ESL 382. After depositing materials of the ESL 382 and the ILD layer 384, a CMP process may be performed to remove excess portions of the ESL 382 and the ILD layer 384 outside the recess R1, thereby forming the dielectric structure 380. Other details of the materials and depositions of the ESL 382 and the ILD layer 384 are similar to those of the ESL 362 and the ILD layer 364 of the dielectric structures 360, and thereto not repeated herein.

In some embodiments of the present disclosure, since the second portion FS2 of the fin FS is free from the channel layers 224 and 210′, the source/drain epitaxial structures 370 may be absent from the second portion FS2 of the fin FS.

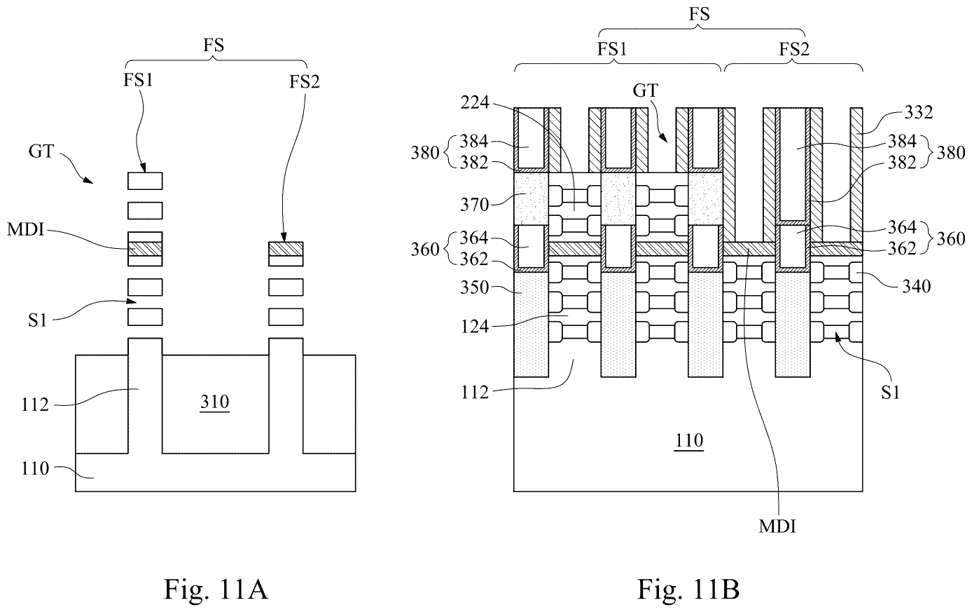

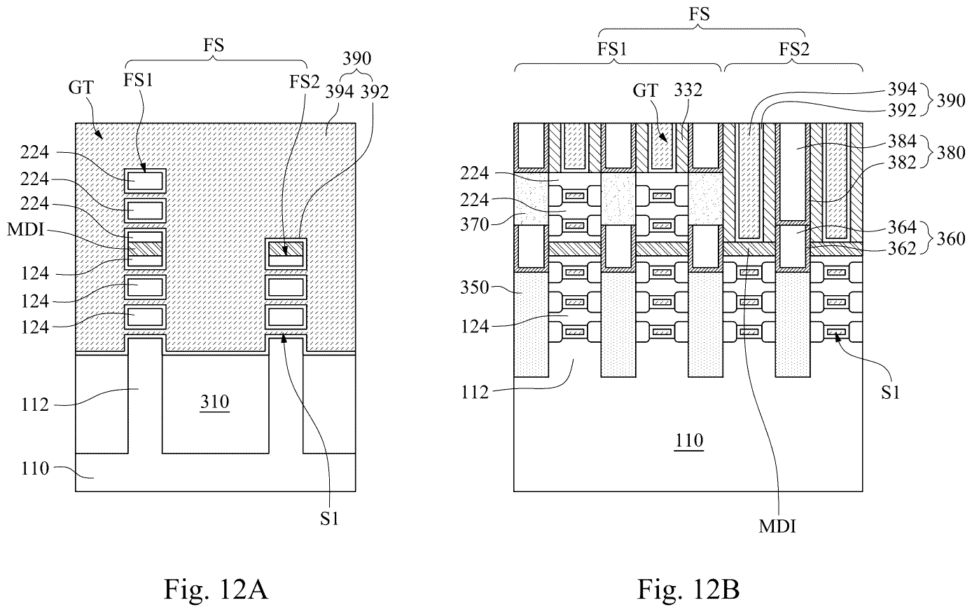

FIGS. 11A-12B show the dummy gate structures 320, the sacrificial layers 122, and the sacrificial layers 222 (referring to FIG. 10B) are replaced with high-k/metal gate structures 390. Reference is made to FIGS. 11A and 11B. The dummy gate structures 320 (referring to FIG. 10B) are removed, followed by removing the sacrificial layers 122 and 222 (referring to FIG. 10B). For example, the dummy gate structures 320 (referring to FIG. 10B) are removed by using a selective etching process (e.g., selective dry etching, selective wet etching, or a combination thereof) that etches the materials in dummy gate structures 320 (referring to FIG. 10B) at a faster etch rate than it etches other materials (e.g., the gate spacers 332, the ESL layer 382, and/or the ILD layer 384), thus resulting in gate trenches GT between corresponding gate spacers 332, with the sacrificial layers 122 and 222 (referring to FIG. 10B) exposed in the gate trenches GT. Subsequently, the sacrificial layers 122 and 222 (referring to FIG. 10B) in the gate trenches GT are etched by using another selective etching process that etches the sacrificial layers 122 and 222 at a faster etch rate than it etches the layers 210′, 224, 124, and the substrate portion 112, thus forming openings/spaces S1 between neighboring layers 210′, 224, 124, and the substrate portion 112. The openings/spaces S1 may expose the sidewalls of the inner spacers 340. In this way, the channel layers 124 become nanosheets suspended over the substrate 110 and between the source/drain epitaxial structures 350, and the channel layers 224 and 210′ become nanosheets suspended over the substrate 110 and between the source/drain epitaxial structures 370. This step is also called a channel release process. At this interim processing step, the openings/spaces S1 surrounding the nanosheets 124, 224, and 210′ may be filled with ambient environment conditions (e.g., air, nitrogen, etc). In some embodiments, the nanosheets 124, 224, and 210′ can be interchangeably referred to as nanowires, nanoslabs and nanorings, depending on their geometry. For example, in some other embodiments, the channel layers 124, 224, and 210′ may be trimmed to have a substantial rounded shape (i.e., cylindrical) due to the selective etching process for completely removing the sacrificial layers 122 and 222 (referring to FIG. 10B). In that case, the resultant channel layers 124, 224, and 210′ can be called nanowires.

In some embodiments, the sacrificial layers 122 and 222 (referring to FIG. 10B) are removed by using a selective dry etching process. In some embodiments, the sacrificial layers 122 and 222 (referring to FIG. 10B) are SiGe and the channel layers 124, 224, and 210′ are silicon allowing for the selective removal of the sacrificial layers 122 and 222 (referring to FIG. 10B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 122 and 222 (referring to FIG. 10B) are removed. Moreover, because oxidation rate of Si is much lower (sometimes 30 times lower) than oxidation rate of SiGe, the channel layers 124, 224, and 210′ and the substrate portion 112 may remain substantially intact during the channel release process.

Reference is made to FIGS. 12A and 12B. Replacement gate structures 390 are then respectively formed in the gate trenches GT to surround each of the nanosheets 124 and 224 suspended in the gate trenches GT. The gate structures 390 may be final gates of GAA FETs. The final gate structure may be a high-k/metal gate stack, however other compositions are possible. In some embodiments, each of the gate structures 390 forms the gate associated with the multi-channels provided by the plurality of nanosheets 124 and 224. For example, the high-k/metal gate structures 390 are formed within the openings/spaces S1 provided by the release of nanosheets 124 and 224. The high-k/metal gate structures 390 may be between the layers 124, 224, 210′ and the substrate portion 112 and surrounded by the inner spacers 340.

In various embodiments, the high-k/metal gate structure 390 includes a gate dielectric layer 392 formed around the nanosheets 124, 224, 210′ and a gate metal layer 394 formed around the dielectric layer 392 and filling a remainder of the gate trenches GT. Formation of the high-k/metal gate structures 390 may include one or more deposition processes to form various gate materials, followed by a CMP processes to remove excessive gate materials, resulting in the high-k/metal gate structures 390 having top surfaces level with a top surface of the dielectric structure 380. Thus, transistors (e.g., GAA FET) are formed, and the high-k/metal gate structure 390 surrounds each of the nanosheets 124, 224, 210′, and thus is referred to as a gate of the transistors (e.g., GAA FET).

The gate dielectric layer 392 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the layers 124, 224, 210′ and the substrate portion 112 exposed in the gate trenches GT are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 394 includes one or more metal layers. For example, the gate metal layer 394 may include one or more work function metal layers stacked one over another and a fill metal filling up a remainder of gate trenches GT. The one or more work function metal layers in the gate metal layer 394 provide a suitable work function for the high-k/metal gate structures 390. For an n-type GAA FET, the gate metal layer 394 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 394 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 394 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

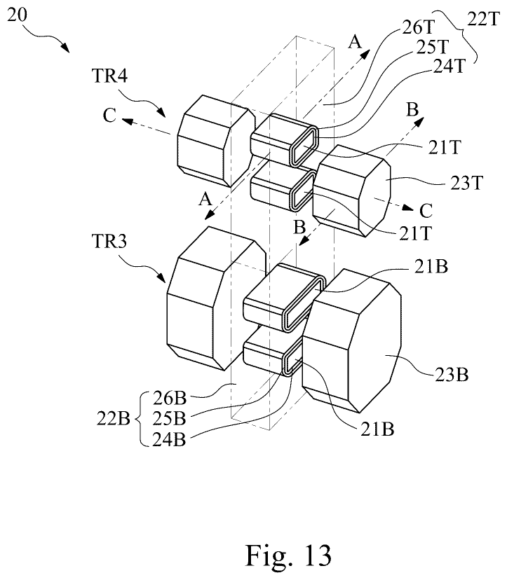

FIG. 13 is a perspective view of an example CFET structure 20 in accordance with some embodiments of the present disclosure. In some embodiments of the present disclosure, a CFET structure 20 includes a bottom transistor TR3 and a top transistor TR4 vertically stacked over the bottom transistor TR3. In some embodiments, the bottom transistor TR3 and the top transistor TR4 are GAA FET transistors. The bottom transistor TR3 includes bottom semiconductor channel layers 21B disposed one above another, a bottom gate structure 22B wrapping around each of the bottom semiconductor channel layers 21B, and bottom source/drain epitaxy structures 23B on opposite sides of each of the bottom semiconductor channel layers 21B. The top transistor TR4 includes top semiconductor channel layers 21T vertically stacked one above another, a top metal gate structure 22T wrapping around each of the top semiconductor channel layers 21T, and top source/drain epitaxy structures 23T on opposite sides of each of the top semiconductor channel layers 21T. The bottom gate structure 22B may include an interfacial layer 24B, a high-k gate dielectric layer 25B around the interfacial layer, and one or more gate metal layers 26B around the high-k gate dielectric layer 25B. The top gate structure 22T may include an interfacial layer 24T, a gate dielectric layer 25T, and a one or more gate metal layers 26T. In some embodiments, the top gate structure 22T can be electrically isolated from bottom gate structure 22B by dielectric bonding materials (not shown), as will be described in greater detail below. In some embodiments, the bottom transistor TR3 has a first conductivity type (e.g., n-type) and the top transistor TR4 has a second conductivity type (e.g., p-type) different from the first conductivity type.

In some embodiments of the present disclosure, the bottom semiconductor channel layers 21B may be wider than the top semiconductor channel layers 21T, such that a size of the bottom source/drain epitaxy structures 23B epitaxially grown on lateral sides of the bottom semiconductor channel layers 21B is greater than a size of the top source/drain epitaxy structures 23T epitaxially grown on lateral sides of the top semiconductor channel layers 21T. For example, a width/size of the source/drain epitaxial structures 23B are greater than a width/size of the source/drain epitaxial structures 23T. The sizes/widths of the source/drain epitaxial structures 23B and 23T can be tuned by deposition parameters in the epitaxial growth process.

FIG. 13 further illustrates reference cross-sections that are used in later figures. Cross-section A-A is along a longitudinal axis of gate structures 22B, 22T and in a direction, for example, perpendicular to the direction of current flow between the epitaxial source/drain structures 23B of the bottom transistor TR3 and the direction of current flow between the epitaxial source/drain structures 23T of the top transistor TR4. Cross-section B-B is parallel to cross-section A-A and extends through epitaxial source/drain structures 23B of the bottom transistor TR3 and epitaxial source/drain structures 23T of the top transistor TR4. Cross-section C-C is perpendicular to cross-sections A-A and B-B and is parallel to the direction of current flow between the epitaxial source/drain structures 23B of the bottom transistor TR3 and the direction of current flow between the epitaxial source/drain structures 23T of the top transistor TR4. Subsequent figures refer to these reference cross-sections for clarity.

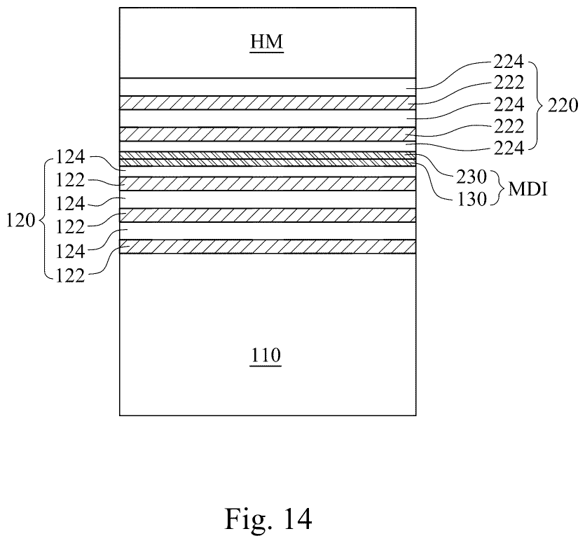

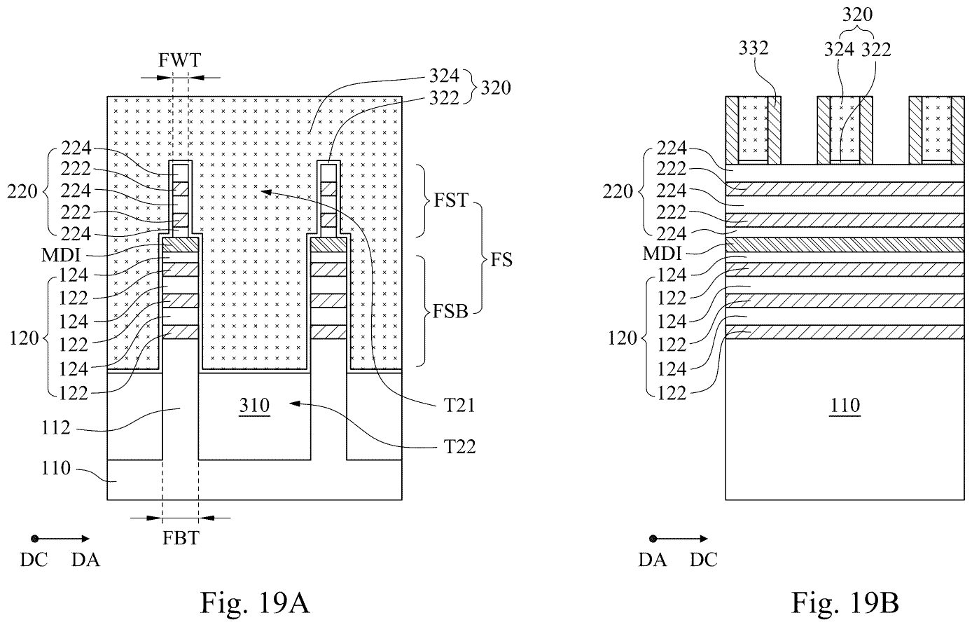

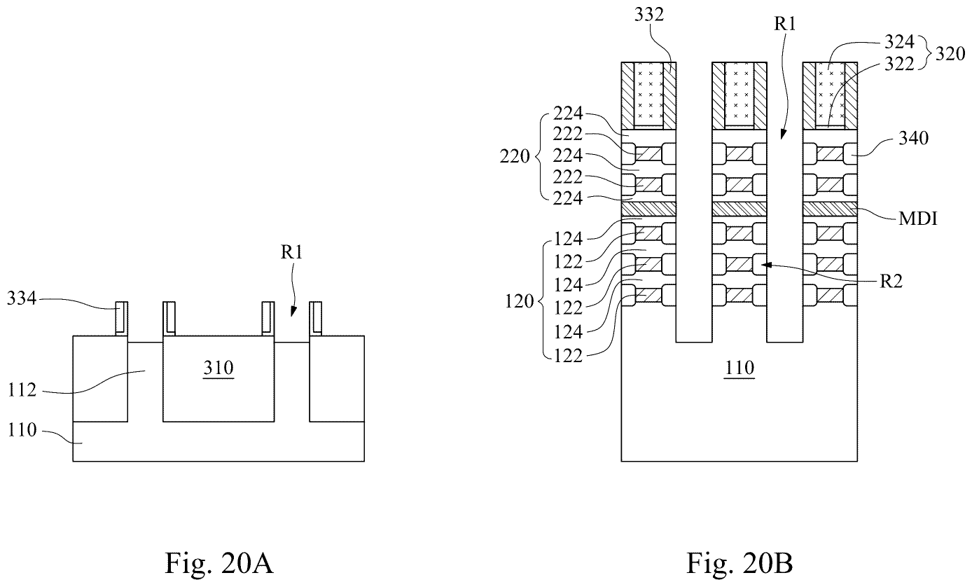

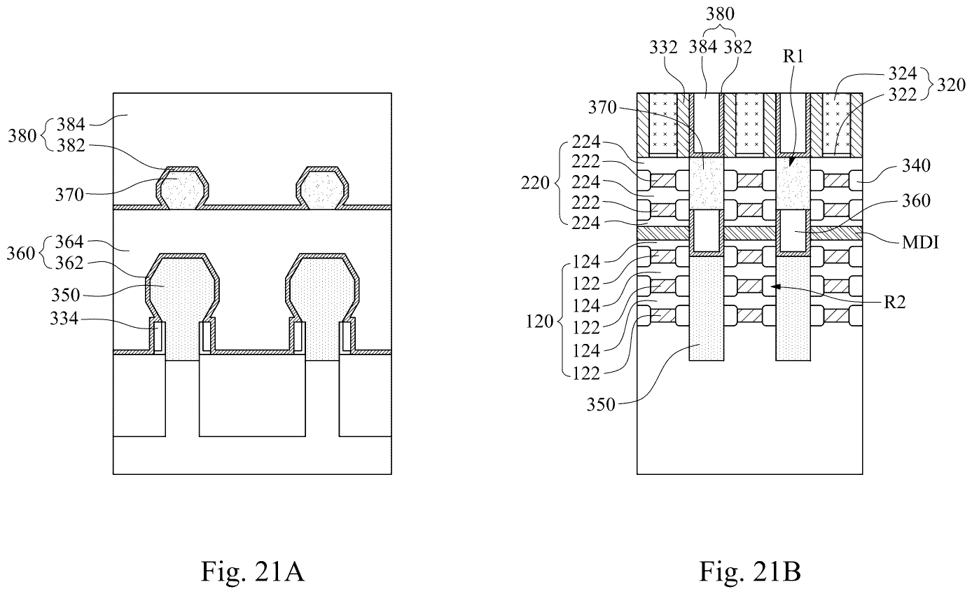

FIGS. 14-23B illustrate schematic views of intermediate stages in the manufacture of an integrated circuit device in accordance with some embodiments of the present disclosure. FIGS. 14-18 are cross-sectional views of the integrated circuit device (e.g., taken along line A-A or B-B in FIG. 13) at various manufacturing stages in accordance with some embodiments. FIGS. 19A, 22A, and 23A are cross-sectional views of the integrated circuit device (e.g., taken along line A-A in FIG. 13) at various manufacturing stages in accordance with some embodiments. FIGS. 20A and 21A are cross-sectional views of the integrated circuit device (e.g., taken along line B-B in FIG. 13) at various manufacturing stages in accordance with some embodiments. FIGS. 19B, 20B, 21B, 22B, and 23B are a cross-sectional view of the integrated circuit device (e.g., taken along line C-C in FIG. 13) at various manufacturing stages in accordance with some embodiments. It is understood that additional steps may be provided before, during, and after the steps shown in FIGS. 14-23B, and some of the steps described below can be replaced or eliminated for additional embodiments of the method. The order of the operations/processes may be interchangeable.

Reference is made to FIG. 14. A hard mask layer HM is formed over the structure of FIG. 4. As aforementioned, the structure of FIG. 4 can be formed by a bonding process and a wafer thinning down process. The hard mask layer HM may include suitable hard mask materials, such as dielectric materials. Exemplary dielectric materials for the hard mask layer HM may include silicon oxide, silicon oxynitride, silicon nitride, the like, or the combination thereof. In some embodiments, the hard mask layer HM may include a same dielectric material as that of the middle dielectric layer MDI.

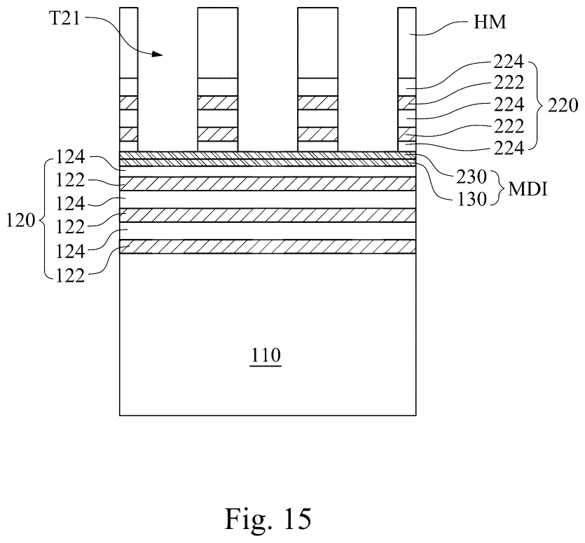

Reference is made to FIG. 15. The hard mask layer HM is patterned to have trenches T21 exposing a portion of the underlying epitaxial stack 220. For example, the patterning process includes a lithography process (e.g., photolithography or e-beam lithography) and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etch (e.g., RIE), wet etch, other etch methods, and/or combinations thereof.

An etching process is performed to remove the portions of the epitaxial stack 220 exposed by the trenches T21, thereby extending the trenches T21 into the epitaxial stack 220. The etching process may be a dry etch (e.g., reactive ion etching), a wet etch, and/or combination thereof. In some embodiments, the etch process has a first etch rate to the epitaxial stack 220 and a second etch rate to the hard mask layer HM, in which the first etch rate is much greater than the second etch rate. Thus, the etching process is performed using the hard mask layer HM as an etch mask. The etching process may extend the trenches T21 into the epitaxial stack 220 until reaching the middle dielectric layer MDI. In some embodiments, the etching process has a first etch rate to the epitaxial stack 220 and a second etch rate to the middle dielectric layer MDI, in which the first etch rate is much greater than the second etch rate. Thus, the middle dielectric layer MDI may serve as an etch stop layer during the etch process, thereby protecting the epitaxial stack 120 from being etched.

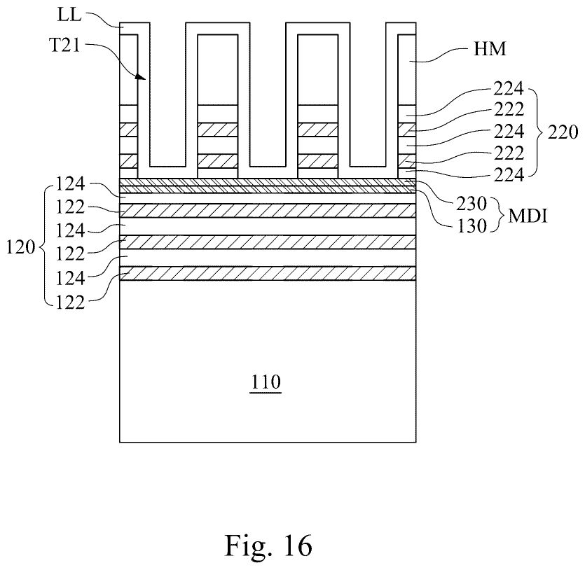

Reference is made to FIG. 16. A liner layer LL is conformally deposited into the trenches T21 and over the hard mask layer HM. The liner layer LL may include suitable dielectric materials, such as silicon oxide, silicon oxynitride, silicon nitride, the like, or the combination thereof. The material of the liner layer LL may be different that of the hard mask layer HM and the middle dielectric layer MDI.

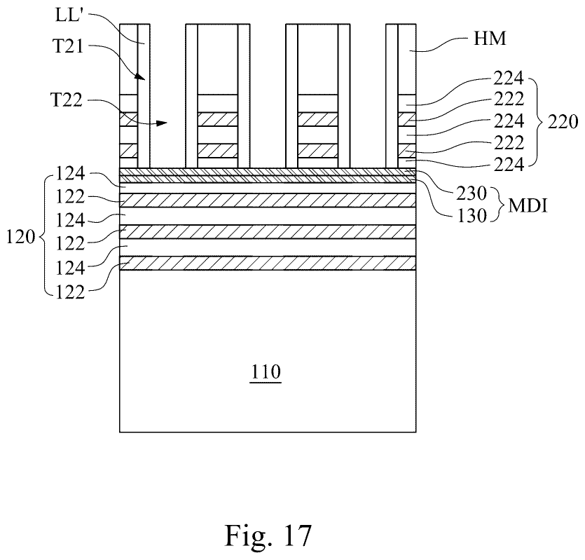

Reference is made to FIG. 17. An anisotropic etching back process is performed to etch through the liner layer LL (referring to FIG. 16), thereby exposing the middle dielectric layer MDI. In some embodiments, the anisotropic etching back process is performed to remove horizontal portions of the liner layer LL (referring to FIG. 16). Remaining portions of the liner layer LL (referring to FIG. 16) may be referred to as liner layers LL′ hereinafter. For example, after the anisotropic etching back process, the liner layers LL′ may have trenches T22 exposing the middle dielectric layer MDI, in which a width of the trenches T22 is substantially equal to a width of the trenches T21 subtracted by twice a thickness of the liner layers LL′. In some embodiments, the anisotropic etching back process has a first etch rate to the liner layer LL and a second etch rate to the hard mask layer HM and the middle dielectric layer MDI, in which the first etch rate is much greater than the second etch rate. Thus, the hard mask layer HM may serve as an etch mask during the anisotropic etching process, thereby protecting the epitaxial stack 220 from being etched. And, the middle dielectric layer MDI may serve as an etch stop layer during the anisotropic etching process, thereby protecting the epitaxial stack 120 from being etched.

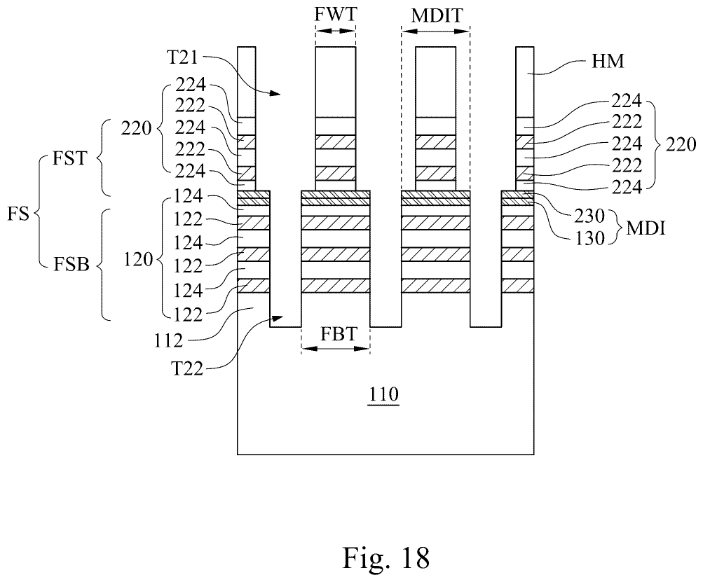

Reference is made to FIG. 18. An etching back process is performed to remove portions of the epitaxial stack 120 exposed by the trenches T22 in the liner layer LL′ (referring to FIG. 17), thereby extending the trenches T22 into the middle dielectric layer MDI and the epitaxial stack 120. The etching back process may be a dry etch (e.g., reactive ion etching), a wet etch, and/or combination thereof. After the etching back process, the liner layer LL′ (referring to FIG. 17) may be removed by suitable liner removal process (e.g., etch/clean process).

Thus, a plurality of semiconductor fins FS extending from the substrate 210 are formed. In various embodiments, each of the fins FS includes a bottom fin FSB and a top fin FST, in which a width FBT of the bottom fin FSB is greater than a width FWT of the top fin FST. The bottom fin FSB may include a substrate portion 112 formed from the substrate 110 and portions of each of the epitaxial layers of the epitaxial stack 120 including epitaxial layers 122 and 124. The top fin FST may include a portion of portions of each of the epitaxial layers of the epitaxial stack 220 including epitaxial layers 222 and 224, and a portion of the channel layer 210′. The middle dielectric layer MDI is between the top fin FST and the bottom fin FSB. The middle dielectric layer MDI may have a width MDIT substantially equal to the width FBT of the bottom fin FSB and greater than the width FWT of the top fin FST.

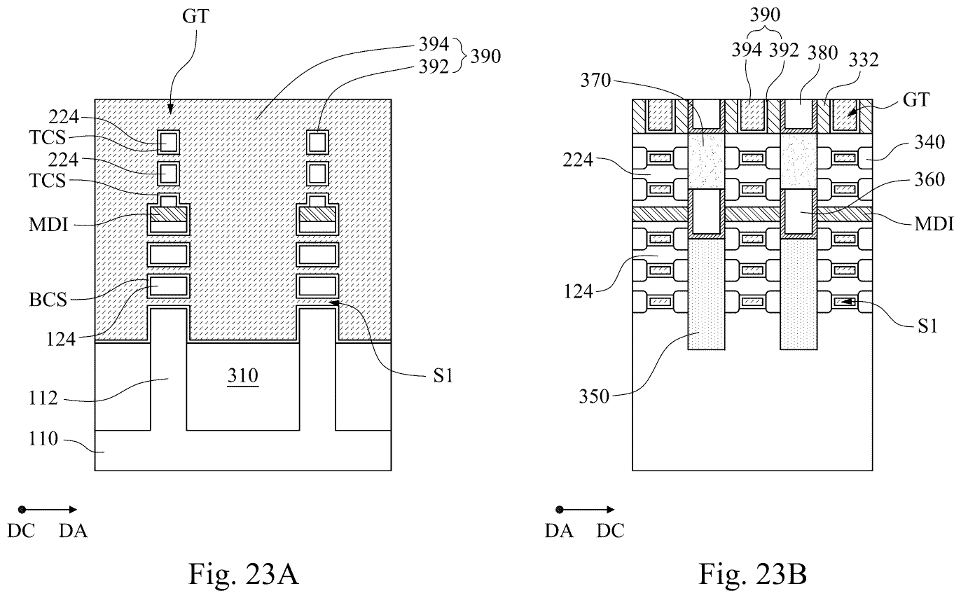

In the context, the width FBT, the width FWT, and the width MDIT may be measured along a longitudinal direction DA of gate structure (e.g., the dummy gate structures 320 in FIG. 19A and/or the replacement gate structure in FIG. 23A) which is substantially perpendicular to the longitudinal direction DC of the fins FS. For example, the longitudinal direction DA is parallel with the line A-A in FIG. 13, and the longitudinal direction DC is parallel with the line C-C in FIG. 13.

Reference is made to FIGS. 19A and 19B. Isolation structures 310 are formed in the trench T22 between the fins FS. The isolation structure 310 may be a single-layer or a multi-layer structure. In some embodiments, the isolation structure 310 includes low-k dielectric materials, SiN, SiCN, SiOC, SiOCN or the like. Formation of the isolation structure 310 may include depositing a dielectric material over the fins FS, followed by an etching back process. Through the etching back process, a top surface of the isolation structure 310 is lowered to a position lower than a bottommost surface of the epitaxial stack 120, such that the sacrificial layers 122, the channel layers 124, sacrificial layers 222, the channel layers 224, and the channel layer 210′ are exposed.

After the formation of the isolation structure 310, one or more dummy gate structures 320 are formed on the fins FS. The dummy gate structure 320 may include a gate dielectric 322 and a gate electrode 324. Gate spacers 332 are formed on opposite sidewalls of the dummy gate structures 320. In some embodiments, fin sidewall spacers 334 (referring to FIG. 20A later) are formed on opposite sides of the fins FS. The gate spacers 332 or/and the fin sidewall spacers 334 may be formed by first depositing one or more conformal spacer material layers and subsequently etching back the one or more spacer material layers to form the gate spacers 332 or/and the fin sidewall spacers 334.

Reference is made to FIGS. 20A and 20B. After formation of the dummy gate structures 320 and the gate spacers 332, exposed portions of the semiconductor fins FS that extend laterally beyond the gate spacers 332 (e.g., in source/drain regions of the fins FS) are etched by using, for example, an anisotropic etching process that uses the dummy gate structures 320 and the gate spacers 332 as an etch mask, resulting in recesses R1 into the semiconductor fins FS and between corresponding dummy gate structures 320.

The sacrificial layers 122 are laterally or horizontally recessed by using suitable selective etching process, resulting in lateral/sidewall recesses R2 vertically between corresponding channel layers 124, and vertically between the channel layer 124 and the substrate portion 112. And, the sacrificial layers 222 are laterally or horizontally recessed by using suitable selective etching process, resulting in lateral/sidewall recesses R2 vertically between corresponding channel layers 224, and vertically between the channel layer 224 and 210′. Subsequently, inner spacers 340 are formed in the recesses R2. Stated differently, the inner spacers 340 may be formed on opposite end surfaces of the laterally recessed sacrificial layers 122 and 222.

Reference is made to FIGS. 21A and 21B. Source/drain epitaxial structures 350 are formed in the recess R1, and in contact with opposite sides of the channel layers 124. Subsequently, dielectric structures 360 are formed in the recess R1 and on the source/drain epitaxial structures 350. Source/drain epitaxial structures 370 are formed in the recess R1 on the dielectric structures 360. Then, dielectric structures 380 are formed in the recess R1 and on the source/drain epitaxial structures 370.

In some embodiments of the present disclosure, due to the width difference between the bottom fin FSB and the top fin FST (referring to FIGS. 18 and 19A), the channel layer 124 are wider than the channel layer 224, such that a size of the bottom source/drain epitaxy structures 350 epitaxially grown on lateral sides of the channel layer 124 is greater than a size of the top source/drain epitaxy structures 370 epitaxially grown on lateral sides of the channel layer 224.

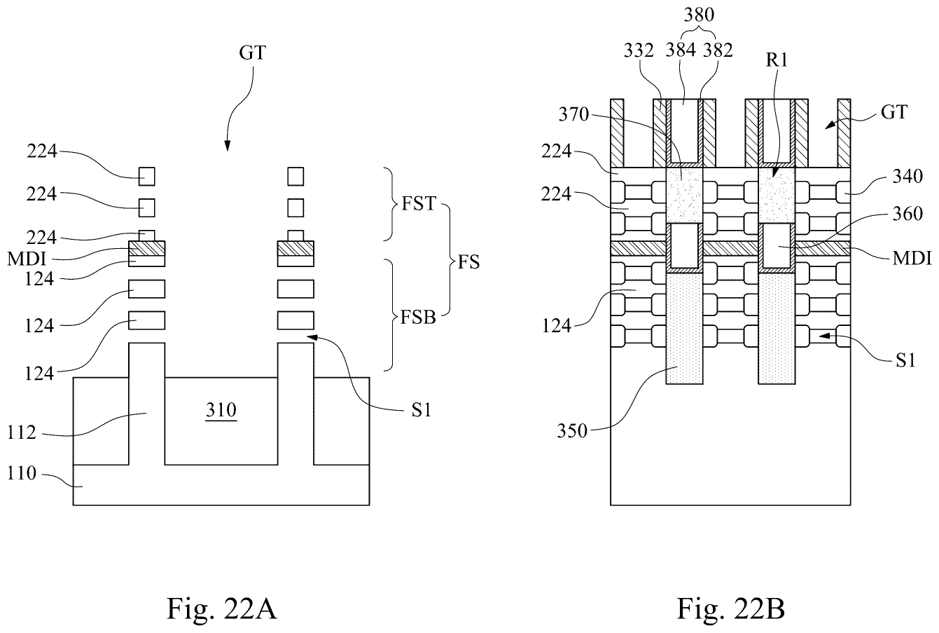

FIGS. 22A-23B shows the dummy gate structure 320, the sacrificial layers 122, and the sacrificial layers 222 (referring to FIG. 22A) are replaced with a high-k/metal gate structure 390. Reference is made to FIGS. 22A and 22B. The dummy gate structures 320 (referring to FIG. 22A) are removed, followed by removing the sacrificial layers 122 and 222 (referring to FIG. 22A). For example, the dummy gate structures 320 (referring to FIG. 22A) are removed by using a selective etching process (e.g., selective dry etching, selective wet etching, or a combination thereof) that etches the materials in dummy gate structures 320 (referring to FIG. 22A) at a faster etch rate than it etches other materials (e.g., the gate spacers 332, the ESL layer 382, and/or the ILD layer 384), thus resulting in gate trenches GT between corresponding gate spacers 332, with the sacrificial layers 122 and 222 (referring to FIG. 22A) exposed in the gate trenches GT. Subsequently, the sacrificial layers 122 and 222 (referring to FIG. 22A) in the gate trenches GT are etched by using another selective etching process that etches the sacrificial layers 122 and 222 at a faster etch rate than it etches the layers 210′, 224, 124, and the substrate portion 112, thus forming openings/spaces S1 between neighboring layers 210′, 224, 124, and the substrate portion 112. The openings/spaces S1 may expose the sidewalls of the inner spacers 340. In this way, the channel layers 124 become nanosheets suspended over the substrate 110 and between the source/drain epitaxial structures 350, and the channel layers 224 and 210′ become nanosheets suspended over the substrate 110 and between the source/drain epitaxial structures 370.

Reference is made to FIGS. 23A and 23B. Replacement gate structures 390 are then respectively formed in the gate trenches GT to surround each of the nanosheets 124 and 224 suspended in the gate trenches GT. The gate structures 390 may be final gates of GAA FETs. The final gate structure may be a high-k/metal gate stack, however other compositions are possible. In some embodiments, each of the gate structures 390 forms the gate associated with the multi-channels provided by the plurality of nanosheets 124 and 224. For example, the high-k/metal gate structures 390 are formed within the openings/spaces S1 provided by the release of nanosheets 124 and 224. The high-k/metal gate structures 390 may be between the layers 124, 224, 210′ and the substrate portion 112 and surrounded by the inner spacers 340.

The replacement gate structures 390 are in contact with the sidewalls TCS of the top channel layers 224 and 210′ and the sidewalls BCS of the bottom channel layers 124. The sidewalls BCS of the bottom channel layers 124 are laterally offset from the sidewalls TCS of the top channel layers 224 and 210′. As shown in FIG. 23A, along the longitudinal direction DA of the gate structure 390, the bottom channel layers 124 and the middle dielectric layer MDI may extend beyond the sidewalls TCS of the top semiconductor channel layers 224 and 210′.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a partial cut nanosheet process is introduced to a CFET fabrication process, thereby reducing effective capacitance and optimizing SRAM performance. Another advantage is that the top and bottom channels in CFET structure are designed with different widths by forming top and bottom nanosheets with different widths, thereby increasing the flexibility of device architecture.

According to some embodiments of the present disclosure, a method for manufacturing an integrated circuit device is provided. The method includes forming a bottom epitaxial stack over a bottom substrate, wherein the bottom epitaxial stack comprises at least one bottom channel layer and at least one bottom sacrificial layer; forming a top epitaxial stack over the bottom epitaxial stack, wherein the top epitaxial stack comprises at least one top channel layer and at least one top sacrificial layer; patterning the top epitaxial stack and the bottom epitaxial stack into a first fin and a second fin; removing a first portion of the top epitaxial stack from the second fin, wherein a second portion of the top epitaxial stack remains in the first fin; epitaxially growing a first bottom source/drain epitaxial structure and a second bottom source/drain epitaxial structure on a side of the bottom channel layer in the first fin and a side of the bottom channel layer in the second fin, respectively; and epitaxially growing a top source/drain epitaxial structure on a side of the top channel layer in the first fin.

According to some embodiments of the present disclosure, a method for manufacturing an integrated circuit device is provided. The method includes forming a bottom epitaxial stack over a bottom substrate, wherein the bottom epitaxial stack comprises at least one bottom channel layer and at least one bottom sacrificial layer; forming a top epitaxial stack over the bottom epitaxial stack, wherein the top epitaxial stack comprises at least one top channel layer and at least one top sacrificial layer; patterning the top epitaxial stack into a top fin; patterning the bottom epitaxial stack into a bottom fin below the top fin, wherein a width of the bottom fin is greater than a width of the top fin; epitaxially growing a bottom source/drain epitaxial structure on a side of the bottom channel layer in the bottom fin; and epitaxially growing a top source/drain epitaxial structure on a side of the top channel layer in the top fin.

According to some embodiments of the present disclosure, an integrated circuit device includes a bottom transistor and a top transistor vertically stacked over the bottom transistor. The bottom transistor includes a bottom semiconductor channel layer; a bottom gate structure wrapping around the bottom semiconductor channel layer; and a bottom source/drain epitaxial structure on a side of the bottom semiconductor channel layer. The top transistor includes a top semiconductor channel layer. The bottom semiconductor channel layer extends beyond a sidewall of the top semiconductor channel layer. The top gate structure wraps around the top semiconductor channel layer. The top gate structure is in contact with the sidewall of the top semiconductor channel layer. The top source/drain epitaxial structure is on a side of the top semiconductor channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an integrated circuit device, comprising:
forming a bottom epitaxial stack over a bottom substrate, wherein the bottom epitaxial stack comprises at least one bottom channel layer and at least one bottom sacrificial layer;
forming a top epitaxial stack over the bottom epitaxial stack, wherein the top epitaxial stack comprises at least one top channel layer and at least one top sacrificial layer;
patterning the top epitaxial stack and the bottom epitaxial stack into a first fin and a second fin;
removing a first portion of the top epitaxial stack from the second fin, wherein a second portion of the top epitaxial stack remains in the first fin;
epitaxially growing a first bottom source/drain epitaxial structure and a second bottom source/drain epitaxial structure on a side of the bottom channel layer in the first fin and a side of the bottom channel layer in the second fin, respectively; and
epitaxially growing a top source/drain epitaxial structure on a side of the top channel layer in the first fin.

2. The method of claim 1, further comprising:
forming a dielectric layer over the bottom epitaxial stack, wherein forming the top epitaxial stack is performed such that the dielectric layer is between the bottom epitaxial stack and the top epitaxial stack.

3. The method of claim 2, wherein removing the first portion of the top epitaxial stack from the second fin is performed such that a top surface of the dielectric layer is exposed by the second portion of the top epitaxial stack.

4. The method of claim 2, wherein removing the first portion of the top epitaxial stack from the second fin is performed such that the dielectric layer extends beyond a sidewall of the second portion of the top epitaxial stack in the first fin.

5. The method of claim 1, further comprising:
after removing the first portion of the top epitaxial stack from the second fin, forming a dummy gate structure around the first and second fins; and
after epitaxially growing the top source/drain epitaxial structure, replacing the dummy gate structure, the top sacrificial layer, and the bottom sacrificial layer with a high-k/metal gate structure.

6. The method of claim 1, wherein removing the first portion of the top epitaxial stack from the second fin comprises:
forming a patterned mask covering the first fin and exposing the second fin; and
with the patterned mask in place, etching away the first portion of the top epitaxial stack from the second fin.

7. The method of claim 1, wherein forming the top epitaxial stack over the bottom epitaxial stack comprises:
forming the top epitaxial stack over a top substrate; and
bonding the bottom substrate to the top substrate.

8. A method for manufacturing an integrated circuit device, comprising:
forming a bottom epitaxial stack over a bottom substrate, wherein the bottom epitaxial stack comprises at least one bottom channel layer and at least one bottom sacrificial layer;
forming a top epitaxial stack over the bottom epitaxial stack, wherein the top epitaxial stack comprises at least one top channel layer and at least one top sacrificial layer;
patterning the top epitaxial stack into a top fin;
patterning the bottom epitaxial stack into a bottom fin below the top fin, wherein a width of the bottom fin is greater than a width of the top fin;
epitaxially growing a bottom source/drain epitaxial structure on a side of the bottom channel layer in the bottom fin; and
epitaxially growing a top source/drain epitaxial structure on a side of the top channel layer in the top fin.

9. The method of claim 8, wherein a size of the top source/drain epitaxial structure is less than a size of the bottom source/drain epitaxial structure.

10. The method of claim 8, wherein patterning the top epitaxial stack into the top fin comprises:
etching a plurality of top trenches in the top epitaxial stack.

11. The method of claim 10, wherein patterning the bottom epitaxial stack into the bottom fin comprises:
forming a plurality of liner layers in the top trenches; and
with the liner layers in place, etching a plurality of bottom trenches in the bottom epitaxial stack.

12. The method of claim 11, wherein a width of the bottom trenches is less than a width of the top trenches.

13. The method of claim 8, further comprising:
forming a dielectric layer over the bottom epitaxial stack, wherein forming the top epitaxial stack is performed such that the dielectric layer is between the bottom epitaxial stack and the top epitaxial stack.

14. The method of claim 13, wherein patterning the top epitaxial stack into the top fin is performed such that the dielectric layer is exposed by the top fin.

15. The method of claim 8, further comprising:
after patterning the bottom epitaxial stack into the bottom fin, forming the dummy gate structure around the top and bottom fins; and
after epitaxially growing the top source/drain epitaxial structure, replacing the dummy gate structure, the top sacrificial layer, and the bottom sacrificial layer with a high-k/metal gate structure.

16. An integrated circuit device, comprising:
a bottom transistor, comprising:
a bottom semiconductor channel layer;
a bottom gate structure wrapping around the bottom semiconductor channel layer; and
a bottom source/drain epitaxial structure on a side of the bottom semiconductor channel layer; and
a top transistor vertically stacked over the bottom transistor, comprising:
a top semiconductor channel layer, wherein the bottom semiconductor channel layer extends beyond a sidewall of the top semiconductor channel layer;
a top gate structure wrapping around the top semiconductor channel layer, wherein the top gate structure is in contact with the sidewall of the top semiconductor channel layer; and
a top source/drain epitaxial structure on a side of the top semiconductor channel layer.

17. The integrated circuit device of claim 16, wherein a size of the top source/drain epitaxial structure is less than a size of the bottom source/drain epitaxial structure.

18. The integrated circuit device of claim 16, further comprising:
a dielectric layer between the top transistor and the bottom transistor, wherein the dielectric layer extends beyond the sidewall of the top semiconductor channel layer.

19. The integrated circuit device of claim 16, further comprising:
a dielectric layer between the top transistor and the bottom transistor, and a width of the dielectric layer measured along a longitudinal direction of the bottom gate structure is greater than the second width.

20. The integrated circuit device of claim 16, wherein the bottom semiconductor channel layer has a first width measured along a longitudinal direction of the bottom gate structure, the top semiconductor channel layer has a second width measured along a longitudinal direction of the top gate structure, and the second width is less than the first width.
